(19) United States
(12) Patent Application Publication
(10) Pub. No.: US 2025/0143002 A1
(43) Pub. Date: May 1, 2025

(54) IMAGE SENSOR MODULE

(71) Applicant: Samsung Electronics Co., Ltd., Suwon-si (KR)

(72) Inventors: Kyungsung CHU, Suwon-si (KR); In-Sang SONG, Suwon-si (KR)

(73) Assignee: Samsung Electronics Co., Ltd., Suwon-si (KR)

(21) Appl. No.: 18/647,396

(22) Filed: Apr. 26, 2024

(30) Foreign Application Priority Data
Nov. 1, 2023 (KR) 10-2023-0149044

(51) Int. Cl. H01L 27/146

(52) U.S. Cl. CPC H10F 39/811; H10F 39/804; H10F 39/8063

(57) ABSTRACT

An image sensor module according to some example embodiments includes a reinforcement plate; a substrate on the reinforcement plate and defining a cavity; an image sensor chip in the cavity and configured to convert externally collected light to an electrical signal; an adhesive member along an upper edge of the image sensor chip; an optic filter on the adhesive member and defining an open region extending into a center of the optic filter, the optic filter covering an upper surface of the image sensor chip; and a bonding wire of which a first end is connected with the image sensor chip through the adhesive member and a second end is connected with the substrate.

### CROSS-REFERENCE TO RELATED APPLICATION

This application claims priority to and the benefit of Korean Patent Application No. 10-2023-0149044 filed in the Korean Intellectual Property Office on Nov. 1, 2023, the entire contents of which are incorporated herein by reference.

### BACKGROUND OF THE INVENTION

### (a) Field of the Invention

The present disclosure relates to image sensor modules.

### (b) Description of the Related Art

An image sensor is a sensor that receives light and generates an electrical signal, and is widely applied to digital cameras, smartphones, automobiles, security devices, robots, and the like.

Recently, in accordance with the rapid development of the electrical industry and user demands, electronic devices using image sensors are becoming more down-sized and multi-functional. Accordingly, the size of the substrate on which the image sensor is mounted has increased in order to down-size and multi-functionalize a module containing the image sensor, and research on packaging technology to effectively mount the image sensor on the substrate is actively underway.

In the case of image sensor modules in which a large-sized optical system is used to implement fine pixels, the size of the substrate increases, and a separate support structure is needed to support an optical filter, and the like within the module, thereby causing an increase of the height and footprint of the module.

### SUMMARY OF THE INVENTION

Some aspects provide image sensor modules that can reduce a height and a footprint.

An image sensor module according to some example embodiments includes a reinforcement plate; a substrate on the reinforcement plate, the substrate defining a cavity; an image sensor chip in the cavity and configured to convert externally collected light to an electrical signal; an adhesive member along an upper edge of the image sensor chip; an optic filter on the adhesive member and defining an open region extending into a center of the optic filter, the optic filter covering an upper surface of the image sensor chip; and a bonding wire of which a first end is connected with the image sensor chip through the adhesive member and a second end is connected with the substrate.

An image sensor module according to some example embodiments includes a reinforcement plate; a substrate on the reinforcement plate and defining a cavity; an image sensor chip in the cavity and configured to convert externally collected light to an electrical signal; an adhesive member along an upper edge of the image sensor chip; an optic filter in the cavity and on the adhesive member covering an upper surface of the image sensor chip; and a bonding wire of which a first end is connected with the image sensor chip, the bonding wire configured to electrically connect the image sensor chip and the substrate, and a second end is connected with the substrate, the optic filter defining an open region extending into a center of the optic filter, and the first end of the bonding wire is in the open region.

An image sensor module according to some example embodiments includes a reinforcement plate; a substrate on the reinforcement plate, the substrate defines a cavity and includes a substrate pad; an image sensor chip in the cavity, including a chip pad at an upper edge, and configured to convert externally collected light to an electrical signal; an adhesive member along the upper edge of the image sensor chip and covering the image sensor chip; an optic filter on the adhesive member and defining an open region extending into a center of the optic filter, the optic filter covering an upper surface of the image sensor chip; and a bonding wire including a first end connected to the chip pad by penetrating the adhesive member and configured to electrically connect the image sensor chip and the substrate and a second end connected to the substrate pad, the first end of the bonding wire is in the open region and exposed by the optic filter.

According to some example embodiments, interference between the optic filter and the bonding wire can be prevented or reduced through the optic filter in which a part of the edge is cut and removed.

Accordingly, the optical filter with a part of the edge cut and removed can be attached on the image sensor chip, thereby reducing the height and footprint of the image sensor module.

### BRIEF DESCRIPTION OF THE DRAWINGS

FIG. 1 is an exploded perspective view of an image sensor module according to some example embodiments.

FIG. 2 is a cross-sectional view of the image sensor module of some example embodiments.

FIG. 3 is an enlarged view of the portion A of FIG. 2.

FIG. 4 and FIG. 5 are cross-sectional view of FIG. 2 in the B-B direction.

FIG. 6 is a perspective view of the optic filter in the image sensor module according to some example embodiments.

FIG. 7 is a top plan view of the optic filter of the image sensor module according to some example embodiments.

FIG. 8 shows another shape of the optic filter of the image sensor module according to some example embodiments.

FIG. 9 is a cross-sectional view of an image sensor module according to some example embodiments.

FIG. 10 is an enlarged view of the portion C of FIG. 9.

### DETAILED DESCRIPTION OF SOME EXAMPLE EMBODIMENTS

Hereinafter, with reference to the accompanying drawing, some example embodiments will be described in detail such that a person of an ordinary skill can easily implement it in the technical fields to which the present inventions belong. As those skilled in the art would realize, the described example embodiments may be modified in various different ways, all without departing from the spirit or scope of the present inventions.

The drawings and description are to be regarded as illustrative in nature and not restrictive. Like reference numerals designate like elements throughout the specification.

In addition, since the size and thickness of each component shown in the drawing are arbitrarily indicated for better understanding and ease of description, the present inventions are not necessarily limited to the drawings.

Throughout the specification, when it is described that an element is “connected” to another element, it includes not only a case that it is “directly connected” but also a case that it is “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be understood that when an element such as a layer, film, region, or substrate is referred to as being “on” another element, it can be directly on the other element or intervening elements may also be present.

Further, throughout the specification, the phrase “on a plane” means viewing a target portion from the top, and the phrase “on a cross-section” means viewing a cross-section formed by vertically cutting a target portion from the side.

Hereinafter, an image sensor module according to some example embodiments will be described.

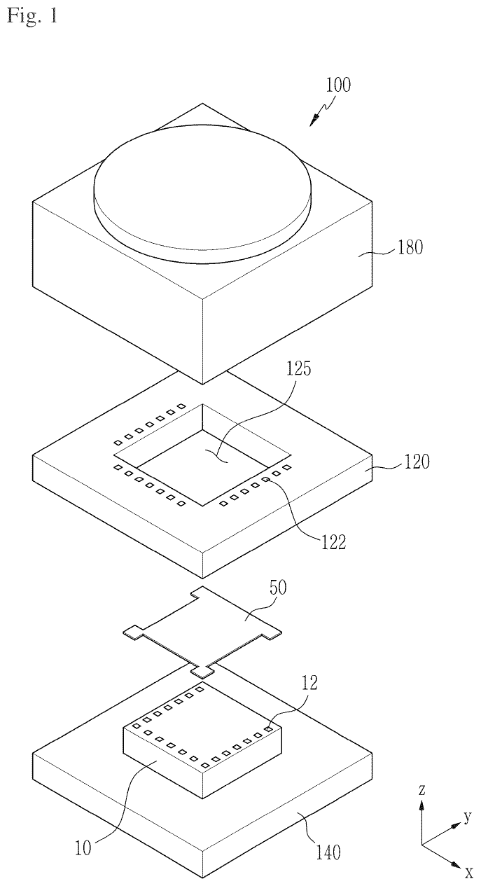

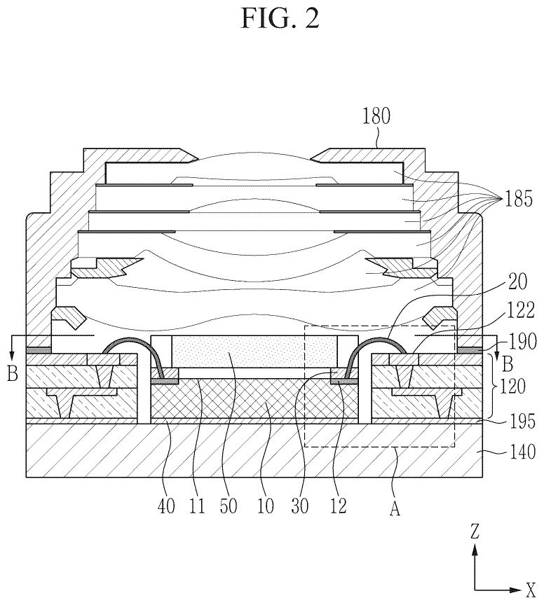

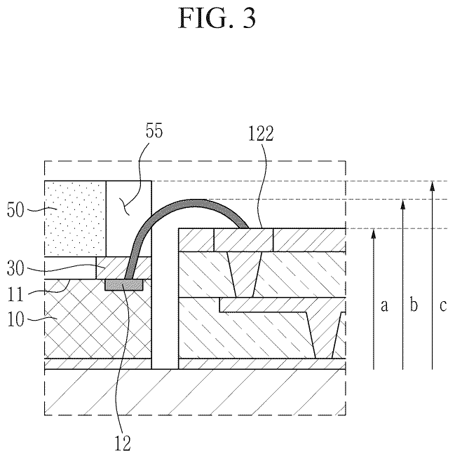

FIG. 1 is an exploded perspective view of an image sensor module according to some example embodiments, FIG. 2 is a cross-sectional view of the image sensor module of some example embodiments, and FIG. 3 is an enlarged view of the portion A of FIG. 2. For convenience in understanding, an adhesive member and a bonding wire are omitted in FIG. 1.

Referring to FIG. 1 to FIG. 3, an image sensor module 100 of some example embodiments includes an image sensor chip 10, a reinforcement plate 140, a substrate 120, a bonding wire 20, an adhesive member 30, and an optic filter 50. In addition, a lens holder 180 coupled with the substrate 120 may be further included on an upper portion of the image sensor chip 10.

As a device that changes externally collected light to an electrical signal, the image sensor chip 10 may include, for example, a CMOS image sensor (CIS) and a charge-coupled device (CCD).

One side (e.g., a top surface) of the image sensor chip 10 may include a sensing area 11 and an outer area around the sensing area 11.

The image sensor chip 10 may include a sensing area and an outer area surrounding the sensing area. The sensing area may include a pixel array including a plurality of unit pixels. The plurality of unit pixels may be arranged in a two-dimensional array. The plurality of unit pixels may be, for example, a passive pixel sensor or an active pixel sensor. The plurality of unit pixels each may include a photodiode that senses light, a transfer transistor that transmits charges generated by the photodiode, a floating diffusion region that stores the transmitted charge, a reset transistor that periodically resets the floating diffusion region, and a source follower that buffers a signal according to the charge charged in the floating diffusion region.

A plurality of color filters and a plurality of micro lenses that are sequentially arranged on a plurality of unit pixels may be disposed on the sensing area. The plurality of color filters may include, for example, a red (R) filter, a blue (B) filter, and a green (G) filter. Alternatively, the plurality of color filters may include a cyan (C) filter, a yellow (Y) filter, and a magenta (M) filter. On the plurality of unit pixels, a color filter formed on one of the R filter, the B filter, and the G filter, or a color filter formed of one of the C filter, the Y filter, and the M filter may be disposed. The plurality of unit pixels may recognize one color by detecting separate components of incident light. The plurality of micro lenses may focus the light incident on the sensing area into the plurality of unit pixels.

An outer area of the image sensor chip 10 is an area at the periphery of the sensing area, and may be an edge area of the image sensor chip 10. A plurality of chip pads 12 may be provided in the outer area. For example, a plurality of chip pads 12 may be disposed on an upper edge of the image sensor chip 10. The chip pad 12 may be electrically connected with the plurality of unit pixels in the sensing area. The chip pad 12 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, or a combination thereof.

The image sensor chip 10 may be disposed on the reinforcement plate 140.

The reinforcement plate 140 may have a quadrangle shape larger than the image sensor chip 10 on a plane. The reinforcement plate 140 may include a ceramic or metal material. For example, the reinforcement plate 140 may include stainless steel (SUS) or a copper (Cu) alloy. The reinforcement plate 140 may prevent or reduce external impact on the image sensor chip 10 and prevent or reduce warpage of the image sensor chip 10.

The image sensor chip 10 may be attached to an upper surface of the reinforcement plate 140 through the first adhesive layer 40. In addition, an upper surface of the reinforcement plate 140 may be attached to a bottom surface of the substrate 120, which will be described later. The first adhesive layer 40 may include an adhesive material, and for example, may include a die attach film (DAF).

As will be described later, the substrate 120 and the reinforcement plate 140 may be combined such that the image sensor chip 10 can be disposed within the cavity 125 of the substrate 120.

The substrate 120 is a component for packaging the image sensor chip 10 together with the aforementioned reinforcement plate 140, and may include, for example, a printed circuit board (PCB). The substrate 120 may be disposed on the reinforcement plate 140.

The substrate 120 includes one side and the other side, opposing the one side. For example, the substrate 120 includes a top surface that faces the outside and a bottom surface that faces the reinforcement plate. Meanwhile, in the present specification, “upper surface” and “lower surface” refer to surfaces facing upward and downward with reference to the drawing, and may mean the surface facing the Z axis and the surface facing the-Z axis, respectively.

The substrate 120 may be attached to the reinforcement plate 140 by a second adhesive layer 195. According to some example embodiments, the second adhesive layer 195 is disposed between the bottom surface of the substrate 120 and the upper surface of the reinforcement plate 140 and thus the substrate 120 can be combined to the reinforcement plate 140. The second adhesive layer 195 may be formed of a material having adherence, and may include, for example, epoxy resin. In some example embodiments, the first adhesive layer 40 and the second adhesive layer 195 may be different materials, while in some other example embodiments, the first adhesive layer 40 and the second adhesive layer 195 may be the same or similar materials.

The substrate 120 may include the cavity 125. The substrate 120 and the image sensor chip 10 are placed on the reinforcement plate 140, and the image sensor chip 10 may be disposed within the cavity 125 of the substrate 120. The cavity 125 is formed in the substrate 120 and the image sensor chip 10 is disposed in in the cavity 125 such that a height of the image sensor module 100 can be reduced compared to a chip on board (COB) type, which places the image sensor chip 10 on the substrate 120. In addition, the effect of preventing or reducing damage and deformation of the image sensor chip 10 can be further increased.

The cavity 125 may be formed in the shape of a through-hole penetrating from one side to the other side of substrate 120. For example, the cavity 125 may have a shape penetrating from the top to the bottom of the substrate 120 in the Z-axis direction. Alternatively, the cavity 125 may have a quadrangle shape on a plane to correspond to the shape of the image sensor chip 10 disposed within the cavity 125. However, the inventive concepts are not limited thereto, and other shapes may be used, for example, a hexagonal shape, or a curved shape. On a plane, the area of the cavity 125 may be larger than the area occupied by the image sensor chip 10, and an inner surface of the cavity 125 may have a predetermined (or alternatively, desired or selected) gap from the image sensor chip 10.

The substrate 120 may include a plurality of insulation layers and a plurality of wire layers. In addition, the substrate 120 may include a plurality of substrate pads 122 for electrical connection. The substrate pad 122 may be exposed to the outside of the substrate 120 for external electrical connection. The substrate pad 122 may be electrically connected to at least one of the plurality of wire layers described above. For example, the substrate pad 122 may be electrically connected to the wire layer through a conductive via that penetrates the aforementioned insulation layer.

The substrate pad 122 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, or a combination thereof.

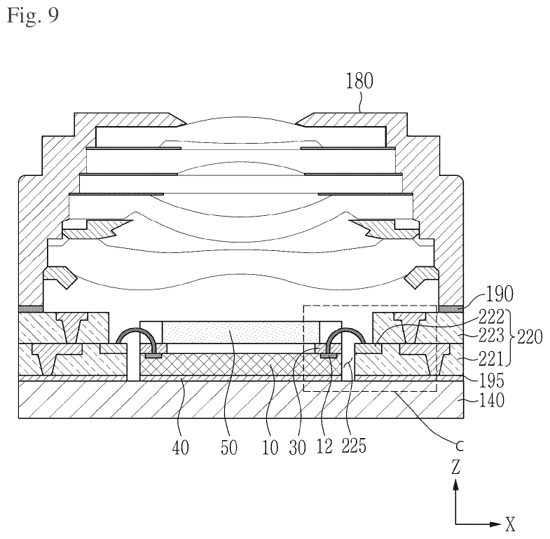

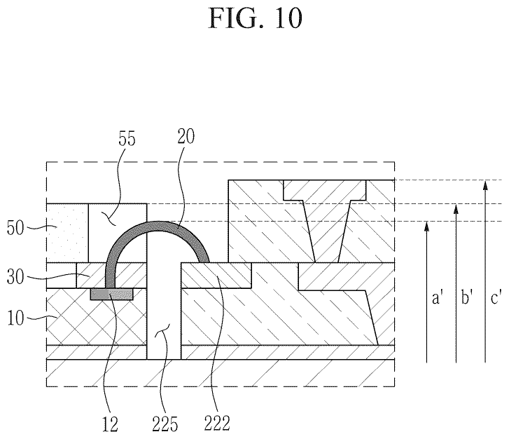

The plurality of substrate pads 122 may be disposed in an area adjacent to the cavity 125. According to some example embodiments, the plurality of substrate pads 122 may be disposed in a circumference portion of the cavity 125 on the upper surface of the substrate 120. In addition, the plurality of substrate pads 122 may be disposed in a direction corresponding to the plurality of chip pads 12. According to some example embodiments, the plurality of substrate pads 122 may be disposed inside the cavity 125 (refer to FIG. 9 and FIG. 10), and this will be described later.

The bonding wire 20 is a conductive member that electrically connects the image sensor chip 10 and the substrate 120. The bonding wire 20 may include a conductive metal such as gold (Au), copper (Cu), and the like.

The bonding wire 20 may be connected with the image sensor chip 10 through one side and connected with the substrate 120 through the other side. According to some example embodiments, as shown in FIG. 2 and FIG. 3, the opposite ends of the bonding wire 20 are connected with the chip pad 12 and the substrate pad 122 such that image sensor chip 10 and the substrate 120 can be electrically connected.

Referring to FIG. 3, a level b of the uppermost surface of the bonding wire 20 may be disposed lower than a level c of the uppermost surface of the optic filter 50. In addition, a part of the bonding wire 20 (e.g., a portion connected to the chip of the bonding wire) may be disposed in an open region 55 of the optic filter 50. In addition, one end of the bonding wire 20, connected to the chip pad 12 may penetrate the adhesive member 30. Accordingly, the optic filter 50 may be attached on the image sensor chip 10, interference between the bonding wire 20 and the optic filter 50 can be prevented or reduced, and the height of the image sensor module 100 can be lowered. This will be described later.

The height of the image sensor module 100 according to some example embodiments can be reduced by attaching the optic filter 50 on the image sensor chip 10 through the adhesive member 30. Hereinafter, the adhesive member 30 and the optic filter 50 will be described in detail with the accompanying drawings.

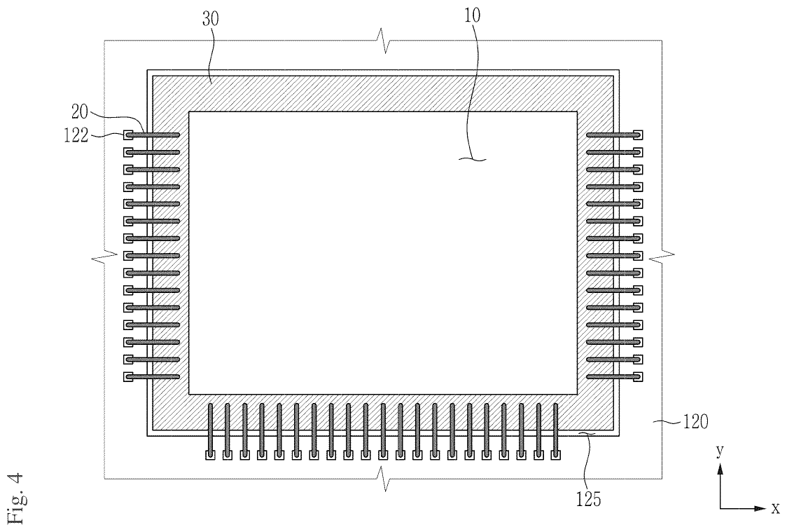

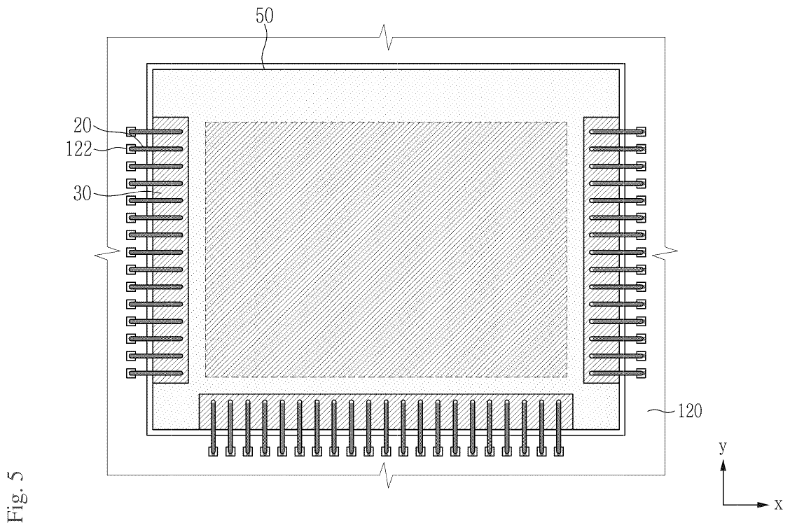

FIG. 4 and FIG. 5 are cross-sectional view of FIG. 2 in the B-B direction. For convenience in understanding, the optic filter 50 is excluded in FIG. 4, and the optic filter 50 is included in FIG. 5.

The adhesive member 30 is a member for attaching the optic filter 50 on the image sensor chip 10. Referring to FIG. 2 to FIG. 5, the adhesive member 30 may be placed along an upper edge of the image sensor chip 10. According to some example embodiments, as shown in FIG. 4 and FIG. 5, the adhesive member 30 may have a ring shape on a plane. For example, the adhesive member 30 may cover the chip pad 12.

The adhesive member 30 may have a predetermined (or alternatively, desired or selected) thickness. The adhesive member 30 may have an overall uniform thickness. In addition, adhesive member 30 may be manufactured in various thicknesses as needed.

The adhesive member 30 may include a non-conductive adhesive film. According to some example embodiments, the adhesive member 30 may include a die attach film (DAF). According to some example embodiments, the adhesive member 30 may be formed by applying a liquid adhesive material to the upper edge of the image sensor chip 10 and then curing the liquid adhesive material into a solid-phase to form the adhesive member 30.

Referring to FIG. 3 to FIG. 5, one side of the bonding wire 20 is connected with the chip pad 12 of the image sensor chip 10, and according to some example embodiments, one end of the bonding wire 20 (for example, a portion connected to the chip pad 12) may penetrate the adhesive member 30.

Referring to FIG. 5, a part of the adhesive member 30 may not be covered by the optic filter 50 and thus exposed from the optic filter 50. Although the optic filter 50 will be described later, the optic filter 50 may have a region (defined as an open region in this specification) where a part of the edge is cut and removed, and according to some example embodiments, a part of the adhesive member 30 may be disposed in the open region of the optic filter 50. That is, the open region may be an empty space that extends from an edge of the optic filter 50 towards the center thereof. The open region may be defined by the edge of the optic filter, for example, the recessed or removed edge. Accordingly, even though the optic filter 50 is directly attached on the image sensor chip 10 by the adhesive member 30, the bonding wire 20 connected to the image sensor chip 10 may not be interfered by the optic filter 50.

The optic filter 50 is a part that passes or blocks light of a specific wavelength band. For example, the optic filter 50 may include an IR filter that filter infrared or near-infrared rays. The optic filter 50 may include a glass material. Alternatively, the optic filter 50 may include a film material.

Referring to FIG. 2 and FIG. 3, the optic filter 50 is disposed on the adhesive member 30 and thus may cover the upper surface of the image sensor chip 10. The optic filter 50 may be placed on the image sensor chip 10 by being spaced apart from the image sensor chip 10 by a thickness of the adhesive member 30.

According to some example embodiments, the optic filter 50 may have a shape that corresponds to a planar shape of the image sensor chip 10. For example, on a plane, the optic filter 50 may have a quadrangle shape of the same size as the image sensor chip 10.

According to some example embodiments, the optic filter 50 may be disposed inside the cavity 125. As previously described, on a plane, the optic filter 50 has a size corresponding to the image sensor chip 10 and covers the upper surface of the image sensor chip 10, and thus the optic filter 50 may be disposed inside the cavity 125 together with the image sensor chip 10.

Referring to FIG. 3, a level c of the upper surface of the optic filter 50 may be higher than a level b of the uppermost end of the bonding wire 20. Accordingly, it is possible to prevent or reduce the overall height of the image sensor module from increasing due to the bonding wire 20. Meanwhile, the level c of the upper surface of the optic filter 50 may be higher than a level a of the upper surface of the substrate 120.

As described above, the optic filter 50 may be attached directly to the image sensor chip 10 through the adhesive member 30, but may be shaped so as not to interfere with the bonding wire 20. According to some example embodiments, the optic filter 50 may have an open region 55. Here, the open region 55 refers to a region where a part of an edge of the optic filter 50 has been cut and removed. Hereinafter, the following will be described with reference to drawings.

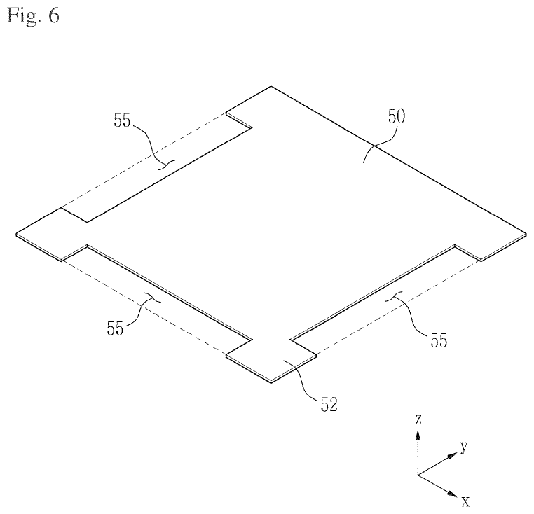

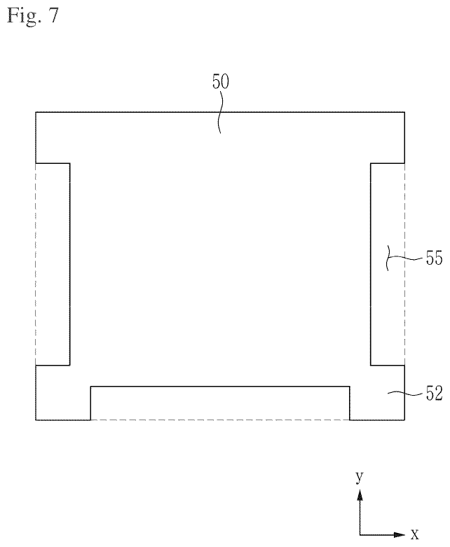

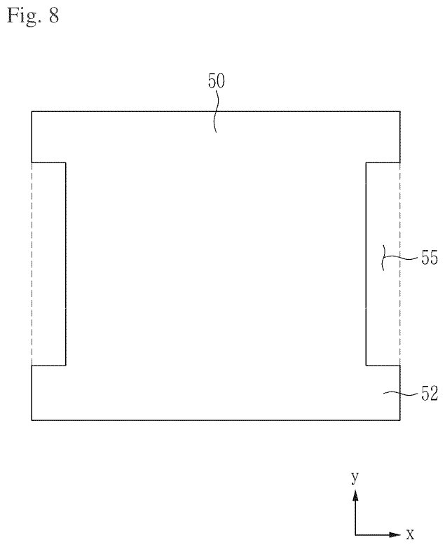

FIG. 6 is a perspective view of the optic filter in the image sensor module according to some example embodiments, and FIG. 7 is a top plan view of the optic filter of the image sensor module according to some example embodiments. FIG. 8 shows another shape of the optic filter of the image sensor module according to some example embodiments.

Referring to FIG. 6 and FIG. 7, the optic filter 50 may have a square plate shape. According to some example embodiments, the optic filter 50 may have the same size (or similar size) as the image sensor chip 10 on a plane and may have a predetermined (or alternatively, desired or selected) thickness. In some example embodiments, the optic filter 50 may have a same outermost boundary shape as the image sensor chip 10 with a different outline, for example, two rectangles of similar outermost dimensions with the optic filter 50 having a cutout thereof.

Referring to FIG. 7, on a plane, the optic filter 50 may have an open region 55 at least one corner. For example, as shown in FIG. 6 and FIG. 7, the open region 55 may be formed at three edge (or side), respectively. In another form, as shown in FIG. 8, the open region 55 may be formed at each of the two edges facing each other. However, the open region 55 is not limited to this, and open region 55 may be formed in only one edge, or open region 55 may be formed in all four edges. For example, the open region 55 may be formed in response to a position where the chip pad 12 is disposed on the image sensor chip 10. However, as an example, the present specification mainly describes the form in which the open regions 55 are formed at each of the three edges.

Referring to FIG. 6 and FIG. 7, when the open region 55 is disposed at one edge of the optic filter 50 having a square plate shape, the open region 55 may be disposed at a predetermined (or alternatively, desired or selected) distance from both vertices at the corners of the one edge. That is, the open region 55 may be disposed at a central portion rather than at both ends of the corner. For example, the open region 55 may not be provided in a corner portion (for example, a vertex portion 52) of the optic filter 50. That is, the vertex portion(s) 52 may define the open region 55 or define lateral boundaries of the open region 55. Accordingly, the weakening of the bonding force of the optic filter 50 with the image sensor chip 10 can be minimized by the open region 55 of the optic filter 50.

The open region 55 may be formed in the square plate-shaped optic filter 50 through a sawing process. Alternatively, for more precise processing, the open region 55 may be formed through a laser cutting process.

Referring to FIG. 5, one side of the bonding wire 20 may be disposed in the open region 55 and exposed from the optic filter 50. When the optic filter 50 does not have an open region 55, the bonding wire 20 interferes with the optic filter 50, and thus the optic filter 50 cannot be attached on the image sensor chip 10. Due to such a problem, a separate structure is needed to support the optic filter 50, which ultimately increases the height and footprint of the entire image sensor module. However, according to some example embodiments, the bonding wire 20 may not interfere with the optical filter 50 through open region 55. Therefore, the optic filter 50 can be directly attached to the image sensor chip 10 via the adhesive member 30, while securing space for the bonding wire 20 to be placed. As a result, the height and footprint of the entire image sensor module can be reduced.

As previously described, the image sensor module 100 according to some example embodiments may further include a lens holder 180. The lens holder 180 may be coupled to the substrate 120. According to some example embodiments, lens holder 180 may be combined with the upper surface of the substrate 120 through a third adhesive layer 190. The third adhesive layer 190 may be formed of a material having adherence, and may include, for example, epoxy resin.

The lens holder 180 may include a plurality of lenses 185 therein. The lens at the bottom inside the lens holder 180 may be arranged to maintain a predetermined (or alternatively, desired or selected) distance from the optical filter 50.

The lens holder 180 may have a square cylinder shape, but is not limited to this. According to some example embodiments, on a plane, the lens holder 180 may have a width less than or equal to that of the substrate 120.

Hereinafter, some example embodiments in which the shape of the substrate is modified will be described. Descriptions of configurations that overlap with the above-described embodiment will be omitted, and only different configurations will be described.

FIG. 9 is a cross-sectional view of an image sensor module according to some example embodiments, and FIG. 10 is an enlarged view of the portion C of FIG. 9.

Referring to FIG. 9 and FIG. 10, a substrate 220 may have a cavity 225 in which through-holes of different sizes are connected. Accordingly, the cavity 225 may have a stepped surface thereon. According to some example embodiments, a substrate pad 222 may be provided on the stepped surface inside the cavity 225.

For example, the substrate 220 may have a form in which a first layer 221 and a second layer 223 are bonded. The first layer 221 and the second layer 223 may each have cavities of different sizes. The cavity of the first layer 221 may be smaller than the cavity of the second layer 223. For example, the substrate 220 may be formed by manufacturing the first layer 221 and the second layer 223 separately and then bonding them.

Alternatively, the substrate 220 may be divided into separate layers constituting one substrate. In the first layer 221 where the cavity 225 is formed, the substrate pad 222 may be formed along a circumference of the cavity 225, and the substrate 220 may be formed by stacking the second layer 223 on the first layer 221 such that the substrate pad 222 is exposed.

In the present embodiment, referring to FIG. 10, a level c′ of an upper surface of the substrate 220 may be higher than a level b′ of an upper surface of the optic filter 50. In addition, the level c′ of the upper surface of the substrate 220 may be higher than a level a′ of an upper surface of a bonding wire 20.

According to some example embodiments as described above, interference between the optic filter 50 and the bonding wire 20 can be prevented or reduced through the optic filter 50 in which a part of the edge is cut and removed. Accordingly, the optic filter 50 can be directly attached to the image sensor chip 10 through the adhesive member 30, thereby reducing the height and footprint of the image sensor module 100.

When the terms “about” or “substantially” are used in this specification in connection with a numerical value, it is intended that the associated numerical value includes a manufacturing or operational tolerance (e.g., ±10%) around the stated numerical value. “Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about”, “generally”, or “substantially” it will be understood that these values and shapes should be construed as including a manufacturing or operational tolerance (e.g., ±10%) around the stated numerical values or shapes.

While this disclosure has been described in connection with what is presently considered to be some practical example embodiments, it is to be understood that the inventive concepts are not limited to the disclosed example embodiments. On the contrary, it is intended to cover various modifications and equivalent arrangements included within the spirit and scope of the appended claims.

### DESCRIPTION OF SYMBOLS

10 image sensor chip
12 chip pad
20 bonding wire
30 adhesive member
50 optic filter
55 open region
100 image sensor module
120, 220 substrate
122, 222 substrate pad
125, 225 cavity
140 reinforcement plate
160 housing
180 lens holder

What is claimed is:

1. An image sensor module comprising:
a reinforcement plate;
a substrate on the reinforcement plate, the substrate defining a cavity;
an image sensor chip in the cavity and configured to convert externally collected light to an electrical signal;
an adhesive member along an upper edge of the image sensor chip;
an optic filter on the adhesive member and defining an open region extending into a center of the optic filter, the optic filter covering an upper surface of the image sensor chip; and
a bonding wire of which a first end is connected with the image sensor chip through the adhesive member and a second end is connected with the substrate.

2. The image sensor module of claim 1, wherein:
the image sensor chip comprises a chip pad on the upper edge,
the substrate comprises a substrate pad in an area adjacent to the cavity, and
the bonding wire is configured to electrically connect the image sensor chip and the substrate through a connection to the chip pad by the first end and the substrate pad by the second end.

3. The image sensor module of claim 1, wherein:
a part of the bonding wire is in the open region.

4. The image sensor module of claim 1, wherein:
an uppermost end of the bonding wire is at a lower level than an uppermost surface of the optic filter.

5. The image sensor module of claim 1, wherein:
an upper surface of the substrate is at a lower level than an upper surface of the optic filter.

6. The image sensor module of claim 1, wherein:
the substrate comprises a first side and a second side opposite to the first side, and the substrate defining the cavity to have a shape that penetrates from the first side of the substrate to the second side of the substrate.

7. The image sensor module of claim 1, wherein:
the substrate defining the cavity to have a stepped surface on an inside of the cavity, the stepped surface includes a substrate pad, and
the second end of the bonding wire is connected to the substrate pad of the stepped surface.

8. The image sensor module of claim 1, wherein:
the optic filter is in the cavity.

9. The image sensor module of claim 1, wherein:
the adhesive member comprises a non-conductive adhesive film.

10. The image sensor module of claim 1, wherein:
a part of the adhesive member is in the open region.

11. An image sensor module comprising:
a reinforcement plate;
a substrate on the reinforcement plate and defining a cavity;
an image sensor chip in the cavity and configured to convert externally collected light to an electrical signal;
an adhesive member along an upper edge of the image sensor chip;
an optic filter in the cavity and on the adhesive member covering an upper surface of the image sensor chip; and
a bonding wire of which a first end is connected with the image sensor chip, the bonding wire configured to electrically connect the image sensor chip and the substrate, and a second end is connected with the substrate,
the optic filter defining an open region extending into a center of the optic filter, and the first end of the bonding wire is in the open region.

12. The image sensor module of claim 11, wherein:
on a plane, the open region is at least one of corners of the optical filter and the optical filter defines the open region being a quadrangular shape, and at a distance from both vertices at the at least one corner.

13. The image sensor module of claim 11, wherein:
the adhesive member has a ring shape on a plane, with a portion in the open region.

14. The image sensor module of claim 11, wherein:
the image sensor chip comprises a chip pad on the upper edge,
the substrate comprises a substrate pad in an area adjacent to the cavity, and
the first end of the bonding wire is connected to the chip pad and the second end of the bonding wire is connected to the substrate pad.

15. The image sensor module of claim 14, wherein:
the adhesive member is penetrated by the first end of the bonding wire connected to the chip pad.

16. The image sensor module of claim 14, wherein:
the substrate defines the cavity having a stepped surface on an inside of the cavity, and
the substrate pad is in the stepped surface.

17. The image sensor module of claim 11, wherein:
the uppermost end of the bonding wire is at a level lower than the uppermost end of the optic filter.

18. An image sensor module comprising:
a reinforcement plate;
a substrate on the reinforcement plate, the substrate defines a cavity and includes a substrate pad;
an image sensor chip in the cavity, including a chip pad at an upper edge, and configured to convert externally collected light to an electrical signal;
an adhesive member along the upper edge of the image sensor chip and covering the image sensor chip;
an optic filter on the adhesive member and defining an open region extending into a center of the optic filter, the optic filter covering an upper surface of the image sensor chip; and
a bonding wire including a first end connected to the chip pad by penetrating the adhesive member and configured to electrically connect the image sensor chip and the substrate and a second end connected to the substrate pad,
the first end of the bonding wire is in the open region and exposed by the optic filter.

19. The image sensor module of claim 18, wherein:
the substrate defines the cavity having a stepped surface on the inside, and
the substrate pad is in the stepped surface.

20. The image sensor module of claim 18, further comprising:
a lens holder including a plurality of lenses inside and coupled on the substate.
